(19) United States
(12) Patent Application Publication
(10) Pub. No.: US 2025/0336835 A1
(43) Pub. Date: Oct. 30, 2025

(54) SEMICONDUCTOR PACKAGE INCLUDING AN INTERPOSER

(71) Applicant: SAMSUNG ELECTRONICS CO., LTD., SUWON-SI (KR)

(72) Inventor: Choongbin Yim, Suwon-si (KR)

(21) Appl. No.: 19/044,203

(22) Filed: Feb. 3, 2025

(30) Foreign Application Priority Data
Apr. 26, 2024 (KR) 10-2024-0056304

(51) Int. Cl. H01L 23/538; H01L 23/00; H01L 23/31; H01L 23/48; H01L 25/07; H01L 25/11

(52) U.S. Cl. CPC H01L 23/5385; H01L 23/481; H01L 23/5386; H01L 24/08; H01L 25/112; H01L 23/3121; H01L 25/074; H01L 2224/08235; H01L 2225/0651; H01L 2225/06541; H01L 2225/1047

(57) ABSTRACT

A semiconductor package includes an interposer, a lower semiconductor chip located on the interposer and including a chip through via, lower stack structures located on the interposer and spaced apart from the lower semiconductor chip in a horizontal direction, a lower molding layer located on the interposer, a redistribution layer located on the lower molding layer, the lower semiconductor chip, and the lower stack structures and electrically connected to the chip through via of the lower semiconductor chip, an upper semiconductor chip located on the redistribution layer and electrically connected to the redistribution layer, upper stack structures spaced apart from the upper semiconductor chip in the horizontal direction, located on the redistribution layer, and electrically connected to the redistribution layer, and an upper molding layer located on the redistribution layer and on side surfaces of the upper semiconductor chip and side surfaces of each of the upper stack structures.

### CROSS-REFERENCE TO RELATED APPLICATION

This application is based on and claims priority under 35 U.S.C. § 119 to Korean Patent Application No. 10-2024-0056304, filed on Apr. 26, 2024, in the Korean Intellectual Property Office, the disclosure of which is incorporated by reference herein in its entirety.

### BACKGROUND

### 1. Technical Field

The inventive concept relates to a semiconductor package, and more particularly, to a semiconductor package including an interposer.

### 2. Discussion of Related Art

Following developments in the electronics industry and the demand of users, electronic devices have become more compact, multifunctional, and large-capacity. Integrated semiconductor chips have been proposed to continue these developments. One avenue of development for a semiconductor package including a highly integrated semiconductor chip includes increasing a number of connection terminals for input/output (I/O), while ensuring connection reliability.

### SUMMARY

The inventive concept provides a semiconductor package with an improved process yield by reducing the size of an interposer substrate.

The inventive concept provides a semiconductor package in which a signal distance between semiconductor chips is reduced.

In addition, aspects of the inventive concept are not limited to those described herein, and other aspects may be clearly understood by one with ordinary skill in the art from the following description.

According to an aspect of the inventive concept, there is provided a semiconductor package including an interposer, a lower semiconductor chip located on the interposer and including a chip through via, a plurality of lower stack structures located on the interposer and spaced apart from the lower semiconductor chip in a horizontal direction, a lower molding layer located on the interposer, a redistribution layer located on the lower molding layer, the lower semiconductor chip, and the plurality of lower stack structures and electrically connected to the chip through via of the lower semiconductor chip, an upper semiconductor chip located on the redistribution layer and electrically connected to the redistribution layer, a plurality of upper stack structures spaced apart from the upper semiconductor chip in the horizontal direction, located on the redistribution layer, and electrically connected to the redistribution layer, and an upper molding layer located on the redistribution layer and on side surfaces of the upper semiconductor chip and side surfaces of each of the plurality of upper stack structures.

According to another aspect of the inventive concept, there is provided a semiconductor package including a lower interposer, a lower semiconductor chip located on the lower interposer and including a chip through via, a mold through via located on the lower interposer and electrically connected to the lower interposer, and spaced apart from the lower semiconductor chip in a horizontal direction, a plurality of lower stack structures located on the lower interposer and spaced apart from the lower semiconductor chip in the horizontal direction, a lower molding layer located on the lower interposer and on side surfaces of the lower semiconductor chip and side surfaces of each of the plurality of lower stack structures, a redistribution layer located on the lower molding layer, the lower semiconductor chip, the mold through via, and the plurality of lower stack structures and configured to be electrically connected to the chip through via, an upper semiconductor chip located on an upper portion of the redistribution layer and electrically connected to the redistribution layer, a plurality of upper stack structures spaced apart from the upper semiconductor chip in the horizontal direction, located on an upper portion of the redistribution layer, and electrically connected to the redistribution layer, and an upper molding layer located on an upper portion of the redistribution layer and on side surfaces of the upper semiconductor chip and side surfaces of each of the plurality of upper stack structures.

According to another aspect of the inventive concept, there is provided a semiconductor package including a package substrate, an interposer located on the package substrate, a lower semiconductor chip located on the interposer and including a chip through via, a chip molding layer located on the interposer and on side surfaces of the lower semiconductor chip, a plurality of lower stack structures located on the interposer and spaced apart from the lower semiconductor chip in a horizontal direction, a lower molding layer located on the interposer and on side surfaces of the chip molding layer and side surfaces of each of the plurality of lower stack structures, a redistribution layer located on the lower molding layer, the lower semiconductor chip, the chip molding layer, and the plurality of lower stack structures, configured to be electrically connected to the chip through via of the lower semiconductor chip, and including a redistribution insulating layer and a bonding pad located inside the redistribution insulating layer, an upper semiconductor chip located on the redistribution layer and electrically connected to the redistribution layer, an upper stack structure spaced apart from the upper semiconductor chip in a horizontal direction, located on the redistribution layer, and electrically connected to the redistribution layer, and an upper molding layer located on the redistribution layer and on side surfaces of the upper semiconductor chip and side surfaces of the upper stack structure.

### BRIEF DESCRIPTION OF THE DRAWINGS

Embodiments will be more clearly understood from the following detailed description taken in conjunction with the accompanying drawings in which:

FIG. 1 is a plan view schematically showing a semiconductor package according to an embodiment;

FIG. 2 is a cross-sectional view schematically showing the semiconductor package of FIG. 1 taken along line A-A′ of FIG. 1;

FIG. 3 is an enlarged view schematically showing a portion “EX1” of the semiconductor package of FIG. 2;

FIG. 4 is a cross-sectional view schematically showing a semiconductor package according to an embodiment;

FIG. 5 is a cross-sectional view schematically showing a semiconductor package according to an embodiment;

FIG. 6 is an enlarged view schematically showing a portion “EX2” of the semiconductor package of FIG. 5;

FIG. 7 is a cross-sectional view schematically showing a semiconductor package according to an embodiment;

FIG. 8 is a cross-sectional view schematically showing a semiconductor package according to an embodiment;

FIG. 9 is a plan view schematically showing a semiconductor package according to an embodiment; and

FIG. 10 is a cross-sectional view schematically showing the semiconductor package of FIG. 9 taken along line B-B′ of FIG. 9.

### DETAILED DESCRIPTION

Hereinafter, embodiments of the inventive concept are described in detail with reference to the accompanying drawings. The same reference numerals are used for the same constituent elements in the drawings, and duplicate descriptions thereof may be omitted.

The disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the disclosure. In the disclosure, certain detailed descriptions may be omitted when they serve to obscure the essence of the inventive concept.

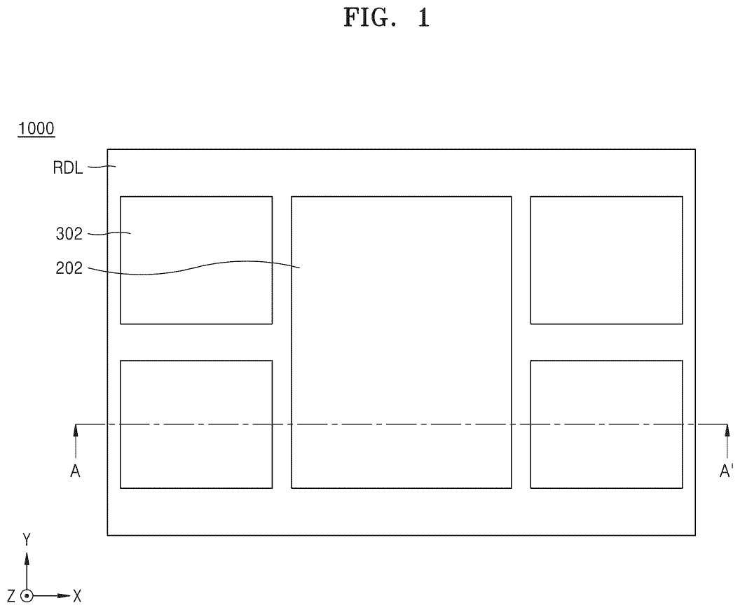

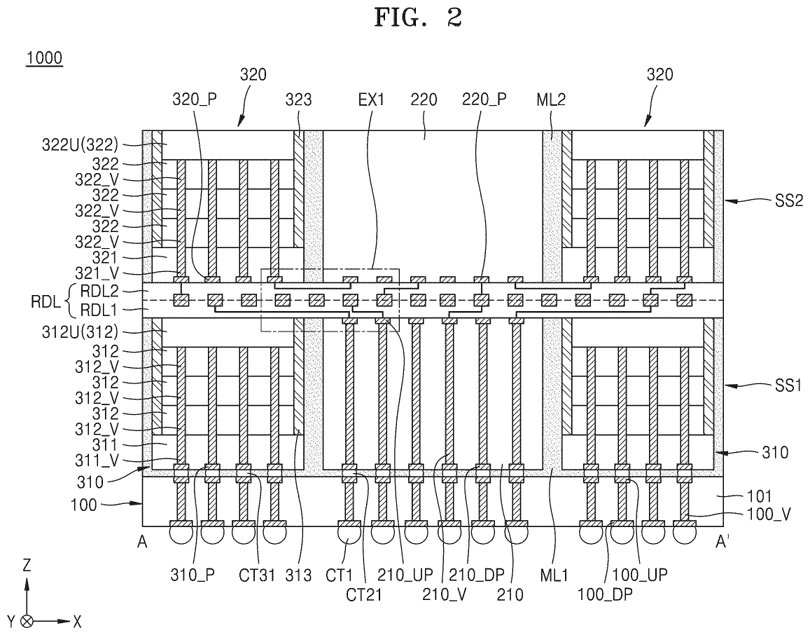

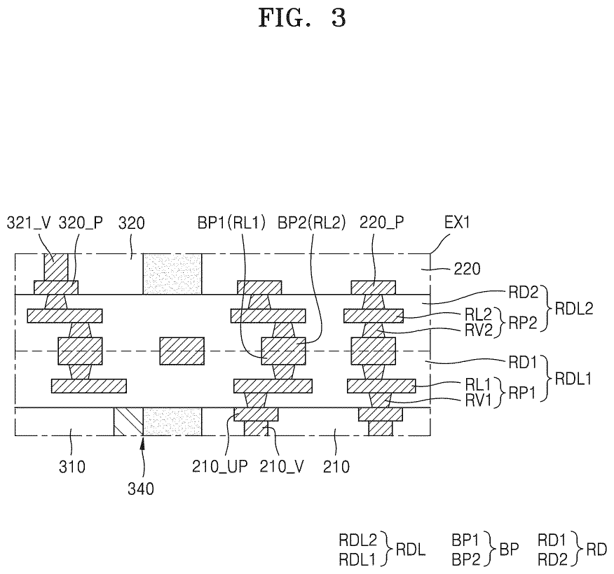

FIG. 1 is a plan view schematically showing a semiconductor package 1000 according to an embodiment. FIG. 2 is a cross-sectional view schematically showing the semiconductor package 1000 of FIG. 1 taken along line A-A′ of FIG. 1. FIG. 3 is an enlarged view schematically showing a portion “EX1” of the semiconductor package 1000 of FIG. 2.

Referring to FIGS. 1 to 3, the semiconductor package 1000 may include an interposer 100, a lower semiconductor chip 210, a plurality of lower stack structures 310, a lower molding layer ML1, a redistribution layer RDL, an upper semiconductor chip 220, a plurality of upper stack structures 320, and an upper molding layer ML2.

Hereinafter, unless otherwise defined, a direction parallel to an upper surface of the interposer 100 may be defined as a first horizontal direction (X direction), a direction perpendicular to the upper surface of the interposer 100 may be defined as a vertical direction (Z direction), and a direction perpendicular to the first horizontal direction (X direction) and the vertical direction (Z direction) may be defined as a second horizontal direction (Y direction). A horizontal direction may be defined as a direction along a plane formed by the first horizontal direction (X direction) and the second horizontal direction (Y direction).

The interposer 100 may include a first substrate 101 and a first through via 100_V penetrating the first substrate 101. For example, the interposer 100 may be a glass interposer in which the first substrate 101 includes glass. In a case that first substrate 101 includes glass, the first through via 100_V may be referred to as a through glass via (TGV). However, the interposer 100 is not limited thereto, and may be a silicon interposer in which the first substrate 101 includes silicon. In a case that first substrate 101 includes silicon, the first through via 100_V may be referred to as a through silicon via (TSV).

The interposer 100 may further include a pad. For example, the interposer 100 may further include an upper pad 100_UP and a lower pad 100_DP. The upper pad 100_UP may be located on an upper surface of the first substrate 101 of the interposer 100, and the lower pad 100_DP may be located on a lower surface of the first substrate 101 of the interposer 100. Each of the upper pad 100_UP and the lower pad 100_DP may be electrically connected to a wiring region of the interposer 100. The upper pad 100_UP and the lower pad 100_DP may be electrically connected to each other by the first through via 100_V. The size of the upper pad 100_UP may be the same as or different than the size of the lower pad 100_DP. In some embodiments, the size of the upper pad 100_UP may be smaller than the size of the lower pad 100_DP.

External connection terminals CT1 may be attached to the lower pad 100_DP. The external connection terminals CT1 may be configured to electrically and physically connect the interposer 100 to an exterior of the semiconductor package 1000. For example, the interposer 100 may be configured to transmit signals between the plurality of lower stack structures 310 and the lower semiconductor chip 210 and an exterior of the semiconductor package. The external connection terminals CT1 may be configured to electrically and physically connect the interposer 100 to an external device on which the interposer 100 may be mounted. The external connection terminals CT1 may be formed from, for example, a solder ball or a solder bump.

The lower semiconductor chip 210 may be located on the interposer 100. For example, the lower semiconductor chip 210 may be located in a central region of the interposer 100. The lower semiconductor chip 210 may include an active surface. The lower semiconductor chip 210 may include an inactive surface disposed opposite to the active surface. In some embodiments, the lower semiconductor chip 210 may include an application specific integrated circuit (ASIC).

In some embodiments, the lower semiconductor chip 210 may be mounted on the interposer 100 such that the active surface of the lower semiconductor chip 210 faces the interposer 100. For example, the lower semiconductor chip 210 may be disposed on the interposer 100 in a face-down manner. However, the lower semiconductor chip 210 is not limited thereto, and may be disposed on the interposer 100 in a face-up manner such that the active surface of the lower semiconductor chip 210 may face away from the interposer 100.

In some embodiments, the lower semiconductor chip 210 may include various types of devices, which may be located on or interfaced through the active surface of the lower semiconductor chip 210. The devices of the lower semiconductor chip 210 may be electrically connected to a wiring region of the lower semiconductor chip 210.

For example, the devices of the lower semiconductor chip 210 may include various microelectronic devices, such as a complementary metal-oxide semiconductor (CMOS) transistor, a metal-oxide-semiconductor filed effect transistor (MOSFET), system large scale integration (LSI), an image sensor such as a CMOS imaging sensor (CIS), a micro-electro-mechanical system (MEMS), an active device, or a passive device.

The lower semiconductor chip 210 may further include a chip through via 210_V. The chip through via 210_V may extend from an upper surface of the lower semiconductor chip 210 to a lower surface. For example, the chip through via 210_V may extend from an active surface of the lower semiconductor chip 210 to an inactive surface. For example, the chip through via 210_V may be electrically connected to the wiring region of the lower semiconductor chip 210.

The lower semiconductor chip 210 may further include a pad. For example, the lower semiconductor chip 210 may include an upper pad 210_UP and a lower pad 210_DP. For example, the upper pad 210_UP of the lower semiconductor chip 210 may be located on the upper surface of the lower semiconductor chip 210 and electrically connected to the wiring region of the lower semiconductor chip 210, and the lower pad 210_DP of the lower semiconductor chip 210 may be located on the lower surface of the lower semiconductor chip 210 and electrically connected to the wiring region of the lower semiconductor chip 210.

In some embodiments, the lower pad 210_DP of the lower semiconductor chip 210 may be electrically connected to the upper pad 100_UP of the interposer 100 through a first connection terminal CT21. The first connection terminal CT21 may be disposed on the interposer 100. The lower molding layer ML1 may be surround side surfaces of the first connection terminal CT21. For example, the lower semiconductor chip 210 may be disposed above the interposer 100 by a height about equal to a thickness of the first connection terminal CT21. However, the inventive concept is not limited thereto, and the lower pad 210_DP of the lower semiconductor chip 210 and the upper pad 100_UP of the interposer 100 may be electrically connected to each other by an anisotropic film (ACF), a non-conductive film (NCF), direct bonding, or hybrid bonding. For example, the first connection terminal CT21 may be omitted, and a space between the lower semiconductor chip 210 and the interposer 100 may not be formed, such that the lower molding layer ML1 may be omitted from between the lower semiconductor chip 210 and the interposer 100.

The plurality of lower stack structures 310 may be located on the interposer 100. The plurality of lower stack structures 310 may be spaced apart from the lower semiconductor chip 210 in a horizontal direction. For example, the plurality of lower stack structures 310 may be mounted on the interposer 100 and located on sides of the lower semiconductor chip 210. The plurality of lower stack structures 310 and the lower semiconductor chip 210 may transmit and receive electrical signals to and from each other through the interposer 100. For example, the interposer 100 may be configured to transmit signals between the plurality of lower stack structures 310 and the lower semiconductor chip 210. The semiconductor package 1000 may include a lower semiconductor chip 210 and a plurality of lower stack structures 310. For example, the semiconductor package 1000 may include a lower semiconductor chip 210 and four lower stack structures 310.

Each of the plurality of lower stack structures 310 may include a lower buffer chip 311, a plurality of lower core chips 312, and a lower core molding layer 313. The lower buffer chip 311 of each of the plurality of lower stack structures 310 may be located at a lowermost end portion of each of the plurality of lower stack structures 310, and the plurality of lower core chips 312 may be stacked in a vertical direction (Z direction) on the lower buffer chip 311. The lower core molding layer 313 may be located on the lower buffer chip 311 and a plurality of lower core chips 312. The lower core molding layer 313 may surround the plurality of lower core chips 312.

For example, an upper surface of the lower core molding layer 313 may be coplanar with an upper surface of an uppermost lower core chip 312U. For example, the upper surface of the uppermost lower core chip 312U may be in contact with the redistribution layer RDL.

Each chip of the lower buffer chip 311 and the plurality of lower core chips 312 may include, for example, a semiconductor material such as silicon (Si) or germanium (Ge). Alternatively, each of the plurality of lower core chips 312 may include a compound semiconductor material such as silicon carbide (SiC), gallium arsenide (GaAs), indium arsenide (InAs), or indium phosphide (InP).

Each chip of the lower buffer chip 311 and the plurality of lower core chips 312 may include an active surface and an inactive surface disposed opposite to the active surface. One or more devices may be disposed on the active surface of each chip of the lower buffer chip 311 and the plurality of lower core chips 312. Each chip of the lower buffer chip 311 and the plurality of lower core chips 312 may include a well doped with impurities, which may be a wiring region. Each chip of the lower buffer chip 311 and the plurality of lower core chips 312 may have various device isolation structures such as a shallow trench isolation (STI) structure.

The semiconductor devices of the lower buffer chip 311 may include various microelectronic devices, for example, a MOSFET such as a CMOS transistor, LSI, an image sensor such as a CIS, a MEMS, an active device, or a passive device. Aspects are not limited thereto, and other devices may be implemented.

The devices of each of the plurality of lower core chips 312 may each include a memory cell. For example, the memory cell may be a nonvolatile memory cell such as flash memory, phase-change random access memory (PRAM), magnetoresistive random access memory (MRAM), ferroelectric random access memory (FeRAM), or resistive random access memory (RRAM). In some embodiments, the memory cell may be a volatile memory cell such as a dynamic random access memory (DRAM) or a static random access memory (SRAM).

The devices of the lower buffer chip 311 may be electrically connected to a wiring region of the lower buffer chip 311, and the devices of each of the plurality of lower core chips 312 may be electrically connected to a wiring region of each of the plurality of lower core chips 312.

In some embodiments, the lower buffer chip 311 may be a semiconductor chip including a serial-parallel conversion circuit, which may control the plurality of lower core chips 312. In some embodiments, the plurality of lower core chips 312 may each be a memory chip including memory cells. For example, each of the plurality of lower stack structures 310 may be a high bandwidth memory (HBM), the lower buffer chip 311 may be referred to as an HBM control die, and each of the plurality of lower core chips 312 may be referred to as a DRAM die.

In some embodiments, a lower core chip located at an uppermost end portion among the plurality of lower core chips 312 may be referred to as the uppermost lower core chip 312U. FIG. 2 shows that the four lower core chips 312 may be stacked in each of the plurality of lower stack structures 310, but the number of lower core chips 312 included in the plurality of lower stack structures 310 is not limited thereto.

In some embodiments, lower core chips excluding the uppermost lower core chip 312U among the plurality of lower core chips 312 may each further include a core through via 312_V. The core through via 312_V may extend from an upper surface of each of the lower core chips 312. The core through via 312_V of each of the plurality of lower core chips 312 may be electrically connected to the wiring region of each of the lower core chips 312. However, the inventive concept is not limited thereto, and the uppermost lower core chip 312U may also include the core through via 312_V.

The plurality of lower core chips 312 may be electrically connected to each other and/or the lower buffer chip 311 through the core through via 312_V. For example, the plurality of lower core chips 312 may be electrically connected to the interposer 100 through the core through via 312_V. For example, a wiring region of the uppermost lower core chip 312U may be electrically connected to the interposer 100 through the core through via 312_V of each of the lower core chips 312 stacked below.

In some embodiments, a thickness of each of the plurality of lower core chips 312, that is, a length according to the vertical direction (Z direction), may be about 20 micrometers (μm) to about 80 μm. The thicknesses of the plurality of lower core chips 312 may have substantially the same value as each other. Alternatively, the thicknesses of the plurality of lower core chips 312 may vary between different lower core chips of the plurality of lower core chips 312.

In some embodiments, a lower pad 310_P may be located on a lower surface of the lower buffer chip 311. The lower pad 310_P of the lower buffer chip 311 may be electrically connected to the wiring region of the lower buffer chip 311 and a buffer through via 311_V of the lower buffer chip 311.

The lower pad 310_P of the lower buffer chip 311 and the interposer 100 may be electrically connected to each other by a second connection terminal CT31. However, the inventive concept is not limited thereto, and the lower pad 310_P of the lower buffer chip 311 and the interposer 100 may be electrically connected to each other by an ACF, an NCF, direct bonding, or hybrid bonding.

The lower molding layer ML1 may be located on the interposer 100 and on side surfaces of each of the plurality of lower stack structures 310 and side surfaces of the lower semiconductor chip 210. The lower molding layer ML1 may surround side surfaces of each of the plurality of lower stack structures 310 and side surfaces of the lower semiconductor chip 210. For example, the lower molding layer ML1 may protect the plurality of lower stack structures 310 and the lower semiconductor chip 210.

In some embodiments, an upper surface of the lower molding layer ML1 may be coplanar with an upper surface of each of the plurality of lower stack structures 310. In some embodiments, the upper surface of the lower molding layer ML1 may be coplanar with an upper surface of the lower semiconductor chip 210. For example, the upper surface of each of the plurality of lower stack structures 310, the upper surface of the lower semiconductor chip 210, and the upper surface of the lower molding layer ML1 may be in contact with the redistribution layer RDL.

For example, the lower semiconductor chip 210 may be in contact with at least one of a lower redistribution via RV1 or a lower redistribution line RL1 of a lower redistribution layer RDL1 of the redistribution layer RDL. For example, a lower redistribution insulating layer RD1 of the lower redistribution layer RDL1 of the redistribution layer RDL may cover the upper surface of each of the plurality of lower stack structures 310.

In some embodiments, the lower molding layer ML1 may include an epoxy resin, or a polyimide resin. However, the inventive concept is not limited thereto. The lower molding layer ML1 may include, for example, an epoxy molding compound (EMC).

In some embodiments, a boundary surface 340 may be between the lower core molding layer 313 of each of the plurality of lower stack structures 310 and the lower molding layer ML1. For example, a curing time between the lower core molding layer 313 and the lower molding layer ML1 may be different such that the boundary surface 340 may be between the lower core molding layer 313 and the lower molding layer ML1. In another example, the lower core molding layer 313 may be cured in advance of the lower molding layer ML1 such that the boundary surface 340 may be between the lower core molding layer 313 and the lower molding layer ML1.

The redistribution layer RDL may be located on the lower molding layer ML1, the lower semiconductor chip 210, and the plurality of lower stack structures 310. For example, the redistribution layer RDL may be in contact with the lower molding layer ML1, the lower semiconductor chip 210, and the plurality of lower stack structures 310. The redistribution layer RDL may be electrically connected to the chip through via 210_V of the lower semiconductor chip 210. The redistribution layer RDL may be electrically connected to the interposer 100 through the chip through via 210_V of the lower semiconductor chip 210.

In some embodiments, a horizontal area of the redistribution layer RDL may be the same as a horizontal area of the interposer 100. For example, in a plan view (see FIG. 1), an area of the upper surface of the redistribution layer RDL may be the same as an area of the upper surface of the interposer 100.

The upper semiconductor chip 220 may be located on the redistribution layer RDL. The upper semiconductor chip 220 may be electrically connected to the redistribution layer RDL. The upper semiconductor chip 220 may be located on a central region of the redistribution layer RDL. For example, the upper semiconductor chip 220 may overlap the lower semiconductor chip 210 in the vertical direction (Z direction). In some embodiments, the upper semiconductor chip 220 may include an ASIC. In some embodiments, the upper semiconductor chip 220 may be the same type of semiconductor chip as the lower semiconductor chip 210. In some embodiments, the upper semiconductor chip 220 may be a different type of semiconductor chip as the lower semiconductor chip 210.

The upper semiconductor chip 220 may include an active surface and an inactive surface disposed opposite to the active surface. In some embodiments, the upper semiconductor chip 220 may be mounted on the redistribution layer RDL such that the active surface of the upper semiconductor chip 220 faces the redistribution layer RDL. For example, the upper semiconductor chip 220 may be disposed on the redistribution layer RDL in a face-down manner.

In some embodiments, the upper semiconductor chip 220 may include various types of devices, which may be located on or interfaced through the active surface of the upper semiconductor chip 220. The devices of the upper semiconductor chip 220 may be electrically connected to a wiring region of the upper semiconductor chip 220.

For example, the devices of the upper semiconductor chip 220 may include various microelectronic devices, for example, a CMOS transistor, a MOSFET, LSI, an image sensor such as a CIS, a MEMS, an active device, or a passive device.

The upper semiconductor chip 220 may include a lower pad 220_P. The lower pad 220_P of the upper semiconductor chip 220 may be located on a lower surface of the upper semiconductor chip 220 and electrically connected to the wiring region of the upper semiconductor chip 220.

The plurality of upper stack structures 320 may be located on the redistribution layer RDL. The plurality of upper stack structures 320 may be spaced apart from the upper semiconductor chip 220 in a horizontal direction. For example, the plurality of upper stack structures 320 may be mounted on the redistribution layer RDL and located on sides of the upper semiconductor chip 220. For example, each of the plurality of upper stack structures 320 may overlap a respective lower stack structure of the plurality of lower stack structures 310 in the vertical direction (Z direction). The plurality of upper stack structures 320 may be electrically connected to the redistribution layer RDL.

The redistribution layer RDL may be configured to transmit an electrical signal between the plurality of upper stack structures 320 and the upper semiconductor chip 220, and between the upper semiconductor chip 220 and the lower semiconductor chip 210. The semiconductor package 1000 may include an upper semiconductor chip 220 and a plurality of upper stack structures 320. For example, the semiconductor package 1000 may include an upper semiconductor chip 220 and four upper stack structures 320.

Each of the plurality of upper stack structures 320 may include an upper buffer chip 321, a plurality of upper core chips 322, and an upper core molding layer 323. The upper buffer chip 321 of each of the plurality of upper stack structures 320 may be located at the lowermost end portion of each of the plurality of upper stack structures 320. The plurality of upper core chips 322 may be stacked in the vertical direction (Z direction) on the upper buffer chip 321. The upper core molding layer 323 may be located on the upper buffer chip 321 and on surfaces of the plurality of upper core chips 322. The upper core molding layer 323 may be located on the upper buffer chip 321 and surround the plurality of upper core chips 322.

For example, an upper surface of the upper core molding layer 323 may be coplanar with an upper surface of an uppermost upper core chip 322U. For example, the upper surface of the uppermost upper core chip 322U may be exposed to the outside of the semiconductor package 1000.

Each chip of the upper buffer chip 321 and the plurality of upper core chips 322 may include, for example, a semiconductor material such as silicon (Si) or germanium (Ge). Alternatively, each of the plurality of upper core chips 322 may include a compound semiconductor material such as silicon carbide (SiC), gallium arsenide (GaAs), indium arsenide (InAs), or indium phosphide (InP).

Each chip of the upper buffer chip 321 and the plurality of upper core chips 322 may include an active surface and an inactive surface disposed opposite to the active surface. One or more semiconductor devices may be formed on or interfaced through the active surface of each chip of the upper buffer chip 321 and the plurality of upper core chips 322. For example, the upper buffer chip 321 may be substantially the same as the lower buffer chip 311. The plurality of upper core chips 322 may be substantially the same as the plurality of lower core chips 312.

In some embodiments, the upper buffer chip 321 may be a semiconductor chip including a serial-parallel conversion circuit, which may control the plurality of upper core chips 322. In some embodiments, the plurality of upper core chips 322 may each be a memory chip including memory cells. For example, each of the plurality of upper stack structures 320 may be a HBM, the upper buffer chip 321 may be referred to as an HBM control die, and each of the plurality of upper core chips 322 may be referred to as a DRAM die. For example, each of the plurality of upper stack structures 320 may be substantially the same type of stack structure as each of the plurality of lower stack structures 310.

In some embodiments, an upper core chip located at an uppermost end portion among the plurality of upper core chips 322 may be referred to as the uppermost upper core chip 322U. FIG. 2 shows that the four upper core chips 322 may be stacked on each of the plurality of upper stack structures 320, but the number of upper core chips 322 included in the plurality of upper stack structures 320 is not limited thereto.

In some embodiments, upper core chips excluding the uppermost upper core chip 322U among the plurality of upper core chips 322 may each further include a core through via 322_V. The core through via 322_V may extend from an upper surface of each of the upper core chips 322. The core through via 322_V of each of the plurality of upper core chips 322 may be electrically connected to a wiring region of each of the upper core chips 322. However, the inventive concept is not limited thereto, and the uppermost upper core chip 322U may also include the core through via 322_V.

The plurality of upper core chips 322 may be electrically connected to each other and/or the upper buffer chip 321 through the core through via 322_V. For example, the plurality of upper core chips 322 may be electrically connected to the redistribution layer RDL through the core through via 322_V. For example, a wiring region of the uppermost upper core chip 322U may be electrically connected to the redistribution layer RDL through the core through via 322_V of each of the upper core chips 322 stacked below.

In some embodiments, a thickness of each of the plurality of upper core chips 322, that is, a length according to the vertical direction (Z direction), may be about 20 μm to about 80 μm. Thicknesses of the plurality of upper core chips 322 may have substantially the same value as each other. Alternatively, the thicknesses of the plurality of upper core chips 322 may very between different upper core chips of the plurality of upper core chips 322.

In some embodiments, the lower pad 320_P may be located on a lower surface of the upper buffer chip 321. The lower pad 320_P of the upper buffer chip 321 may be electrically connected to a wiring region of the upper buffer chip 321 and a buffer through via 321_V of the upper buffer chip 321.

The lower pad 220_P of the upper semiconductor chip 220 and the lower pad 320_P of the upper buffer chip 321 of each of the plurality of upper stack structures 320 may be in contact with the redistribution layer RDL. For example, the upper semiconductor chip 220 and the plurality of upper stack structures 320 may be electrically connected to the redistribution layer RDL, and a separate connection terminal may be omitted. For example, the lower pad 220_P of the upper semiconductor chip 220 and the lower pad 320_P of the upper buffer chip 321 of each of the plurality of upper stack structures 320 may be in contact with an upper redistribution via RV2 of an upper redistribution layer RDL2 of the redistribution layer RDL.

In some embodiments, the upper semiconductor chip 220, the plurality of upper stack structures 320, and the upper molding layer ML2 may be mounted on a carrier substrate. The upper redistribution layer RDL2 may be formed to cover the lower surface of the upper semiconductor chip 220, lower surfaces of the plurality of upper stack structures 320, and a lower surface of the upper molding layer ML2. For example, an upper semiconductor device SS2 may be manufactured in a chip-first manner.

The upper molding layer ML2 may be located on the redistribution layer RDL. The upper molding layer ML2 may be located on side surfaces of each of the plurality of upper stack structures 320 and side surfaces of the upper semiconductor chip 220. The upper molding layer ML2 may surround side surfaces of each of the plurality of upper stack structures 320 and side surfaces of the upper semiconductor chip 220. For example, the upper molding layer ML2 may protect the plurality of upper stack structures 320 and the upper semiconductor chip 220.

In some embodiments, an upper surface of the upper molding layer ML2 may be coplanar with an upper surface of each of the plurality of upper stack structures 320. In some embodiments, the upper surface of the upper molding layer ML2 may be coplanar with an upper surface of the upper semiconductor chip 220. For example, the upper surface of each of a plurality of upper stack structures 320, the upper surface of the upper semiconductor chip 220, and the upper surface of the upper molding layer ML2 may be exposed to the outside of the semiconductor package 1000.

In some embodiments, the upper molding layer ML2 may include an epoxy resin or a polyimide resin. However, the inventive concept is not limited thereto. The upper molding layer ML2 may include, for example, an EMC.

In some embodiments, a boundary surface may be between the upper core molding layer 323 of each of the plurality of upper stack structures 320 and the upper molding layer ML2. For example, a curing time between the upper core molding layer 323 and the upper molding layer ML2 may be different such that the boundary surface may be between the upper core molding layer 323 and the upper molding layer ML2.

In the semiconductor package 1000 of the inventive concept, the redistribution layer RDL on which the upper semiconductor chip 220 and the plurality of upper stack structures 320 may be mounted may be located on an upper portion of each of the lower semiconductor chip 210 and the plurality of lower stack structures 310. For example, the area of the interposer 100 may be relatively reduced. In a manufacturing process of the interposer 100 having a relatively small area, a yield of the interposer 100 may be improved, and a process cost of the interposer 100 may be reduced.

The redistribution layer RDL is described in more detail with reference to FIG. 3.

The redistribution layer RDL may include a redistribution insulating layer RD and a plurality of bonding pads BP. The plurality of bonding pads BP may be buried in the redistribution insulating layer RD. Vertical levels of the plurality of bonding pads BP may be the same as each other. For example, the vertical levels of lower surfaces of the plurality of bonding pads BP may be the same as each other. In the present specification, the vertical level refers to a distance measured from the interposer 100 in the vertical direction (Z direction).

The redistribution layer RDL may be divided into a lower redistribution layer RDL1 and an upper redistribution layer RDL2 disposed on the lower redistribution layer RDL1. A first part of each of the plurality of bonding pads BP of the redistribution layer RDL may be included in the upper redistribution layer RDL2, and a second part of each of the plurality of bonding pads BP may be included in the lower redistribution layer RDL1. For example, the upper redistribution layer RDL2 and the lower redistribution layer RDL1 may be divided with respect to the plurality of bonding pads BP.

The upper redistribution layer RDL2 may include an upper redistribution pattern RP2 and an upper redistribution insulating layer RD2 surrounding the upper redistribution pattern RP2. The upper redistribution pattern RP2 may be electrically connected to the plurality of bonding pads BP. The lower redistribution layer RDL1 may include a lower redistribution pattern RP1 and a lower redistribution insulating layer RD1. The lower redistribution pattern RP1 may be electrically connected to the plurality of bonding pads BP. For example, the lower redistribution insulating layer RD1 and the upper redistribution insulating layer RD2 may be combined and referred to as the redistribution insulating layer RD.

The redistribution insulating layer RD may include an insulating material, for example, a photoimaginable dielectric (PID) resin. In some embodiments, the redistribution insulating layer RD may further include an inorganic filler. In some embodiments, the redistribution insulating layer RD may have a multilayer structure in which a redistribution pattern may be disposed on each layer. For example, each of the upper redistribution insulating layer RD2 and the lower redistribution insulating layer RD1 may have a multilayer structure.

The upper redistribution pattern RP2 may include an upper redistribution line RL2 and an upper redistribution via RV2. The upper redistribution line RL2 may extend in the horizontal direction. The upper redistribution via RV2 may extend in the vertical direction (Z direction) from the upper redistribution line RL2. The upper redistribution line RL2 may be disposed in at least one of an upper surface or a lower surface of the upper redistribution insulating layer RD2. The upper redistribution line RL2 may be disposed inside the upper redistribution insulating layer RD2. The upper redistribution via RV2 may be disposed in at least one of an upper surface or a lower surface of the upper redistribution insulating layer RD2. The upper redistribution via RV2 may penetrate the upper redistribution insulating layer RD2 to be connected to a part of the upper redistribution line RL2.

The lower redistribution pattern RP1 may include a lower redistribution line RL1 and a lower redistribution via RV1. The lower redistribution line RL1 may extend in the horizontal direction. The lower redistribution via RV1 may extend in the vertical direction (Z direction) from the lower redistribution line RL1. The lower redistribution line RL1 may be disposed inside the lower redistribution insulating layer RD1. The lower redistribution line RL1 may be disposed at least one of the upper surface or lower surface of the lower redistribution insulating layer RD1. The lower redistribution via RV1 may be disposed in at least one of an upper surface or a lower surface of the lower redistribution insulating layer RD1. The lower redistribution via RV1 may penetrate the lower redistribution insulating layer RD1 to be connected to a part of the lower redistribution line RL1.

In some embodiments, a width of the upper redistribution via RV2 may increase closer to the interposer 100. For example, the width of the upper redistribution via RV2 may increase downward in the vertical direction (Z direction) by manufacturing the upper redistribution layer RDL2 in a chip-first manner. A width of the lower redistribution via RV1 may decrease closer to the interposer 100. The upper redistribution via RV2 may be in contact with an upper surface of the bonding pad BP. The lower redistribution via RV1 may be in contact with a lower surface of the bonding pad BP.

Each of the upper redistribution pattern RP2 and the lower redistribution pattern RP1 may include a conductive material, for example, copper (Cu), aluminum (Al), silver (Ag), tin (Sn), gold (Au), nickel (Ni), lead (Pb), or titanium (Ti), or alloy thereof.

The semiconductor package 1000 may have a structure in which the upper semiconductor device SS2 including the upper redistribution layer RDL2, the upper semiconductor chip 220, the plurality of upper stack structures 320, and the upper molding layer ML2 may be stacked on a lower semiconductor device SS1 including the interposer 100, the lower semiconductor chip 210, the plurality of lower stack structures 310, and the lower redistribution layer RDL1.

In some embodiments, in a process of stacking the upper semiconductor device SS2 and the lower semiconductor device SS1, the upper redistribution layer RDL2 located at the lowermost end portion of the upper semiconductor device SS2 and the lower redistribution layer RDL1 located at the uppermost end portion of the lower semiconductor device SS1 may be combined into the redistribution layer RDL.

In some embodiments, the redistribution layer RDL may be manufactured by combining the upper redistribution layer RDL2 and the lower redistribution layer RDL1. The redistribution layer RDL may be manufactured by combining the upper redistribution layer RDL2 and the lower redistribution layer RDL1 through hybrid bonding. However, a method of combining the upper redistribution layer RDL2 and the lower redistribution layer RDL1 is not limited thereto.

The upper redistribution layer RDL2 may further include the lower pad BP2 and the upper redistribution line RL2. The lower pad BP2 may be a portion of the upper redistribution line RL2 disposed on the lower surface of the upper redistribution insulating layer RD2 and exposed to the outside of the upper redistribution insulating layer RD2. The lower redistribution layer RDL1 may further include the upper pad BP1 and the lower redistribution line RL1. The upper pad BP1 may be a portion of the lower redistribution line RL1 disposed on the upper surface of the lower redistribution insulating layer RD1 and exposed to the outside of the lower redistribution insulating layer RD1.

In some embodiments, the bonding pad BP may be formed by diffusion bonding the lower pad BP2 of the upper redistribution layer RDL2 and the upper pad BP1 of the lower redistribution layer RDL1 by heat. For example, each bonding pad BP may include a portion disposed in the upper redistribution layer RDL2 and a portion disposed in the lower redistribution layer RDL1. The redistribution insulating layer RD may be formed by diffusion bonding the upper redistribution insulating layer RD2 and the lower redistribution insulating layer RD1 by heat in a process of forming the bonding pad BP.

For example, the bonding pad BP may be formed by diffusion bonding and integrating the lower pad BP2 of the upper redistribution layer RDL2 and the upper pad BP1 of the lower redistribution layer RDL1, and the redistribution insulating layer RD may be formed by diffusion bonding and integrating the upper redistribution insulating layer RD2 and the lower redistribution insulating layer RD1. The diffusion bonding of the lower pad BP2 and the upper pad BP1, and of the upper redistribution insulating layer RD2 and the lower redistribution insulating layer RD1 may be performed simultaneously.

In some embodiments, a thickness of the bonding pad BP may be greater than each of a thickness of the upper redistribution line RL2 and a thickness of the lower redistribution line RL1. For example, the thickness of the bonding pad BP may be the same as a sum of the thickness of the upper redistribution line RL2 and the thickness of the lower redistribution line RL1.

According to an embodiment, in the semiconductor package 1000 of the inventive concept, the upper semiconductor chip 220 and the lower semiconductor chip 210 may overlap in the vertical direction (Z direction), and may be electrically connected to each other, such that a signal distance between the upper semiconductor chip 220 and the lower semiconductor chip 210 may be reduced, generation of noise may be suppressed, and signal reliability may be improved.

According to an embodiment, in the semiconductor package 1000 of the inventive concept, a memory capacity may increase by connecting each of the plurality of lower stack structures 310 and each of the plurality of upper stack structures 320 through the redistribution layer RDL. In addition, a method of stacking stack structures may be more efficient than a method of stacking core semiconductor chips at a high stage, which may reduce a manufacturing cost.

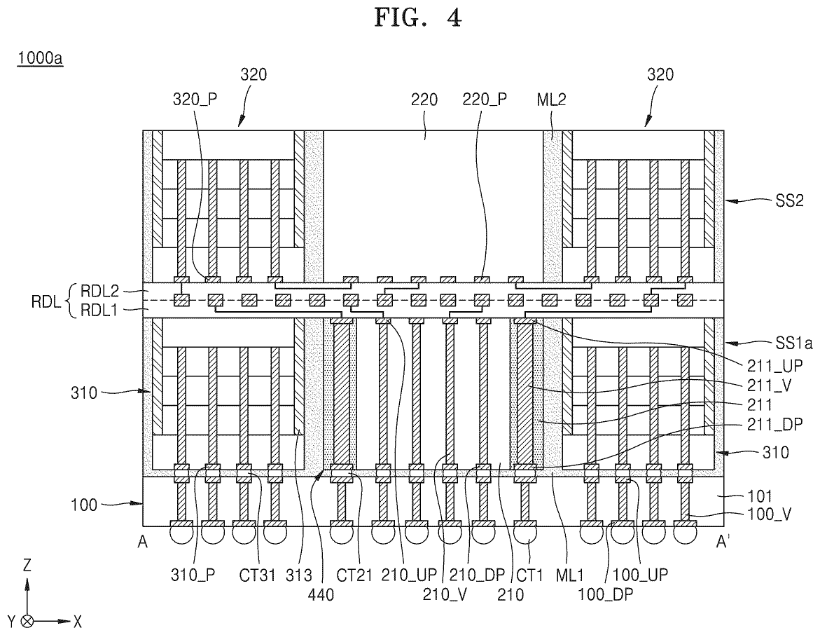

FIG. 4 is a cross-sectional view schematically showing a semiconductor package 1000a according to an embodiment.

Referring to FIG. 4, the semiconductor package 1000a may include an interposer 100, the lower semiconductor chip 210, the chip molding layer 211, the plurality of lower stack structures 310, the lower molding layer ML1, the redistribution layer RDL, the upper semiconductor chip 220, the plurality of upper stack structures 320, and the upper molding layer ML2.

Certain components of the semiconductor package 1000a described below and materials of the components are substantially the same as or similar to those described above with reference to FIG. 2. Therefore, for convenience of explanation, repetitive descriptions thereof may be omitted or simplified.

A lower semiconductor device SS1a may include the interposer 100, the lower semiconductor chip 210, the chip molding layer 211, the plurality of lower stack structures 310, the lower molding layer ML1, and the lower redistribution layer RDL1. The chip molding layer 211 may be located on the interposer 100 and side surfaces of the lower semiconductor chip 210. The chip molding layer 211 may surround side surfaces of the lower semiconductor chip 210. The chip molding layer 211 may be located on the interposer 100 and on the side surfaces of the lower semiconductor chip 210, wherein the chip molding layer 211 separates the side surfaces of the lower semiconductor chip 210 from the lower molding layer ML1. In some embodiments, a thickness of the chip molding layer 211 may be substantially the same as a thickness of the lower semiconductor chip 210. An upper surface of the chip molding layer 211 and an upper surface of the lower semiconductor chip 210 may be coplanar. A lower surface of the chip molding layer 211 and a lower surface of the lower semiconductor chip 210 may be coplanar. For example, the chip molding layer 211 and the lower semiconductor chip 210 may be collectively referred to as a semiconductor chip. The chip molding layer 211 may protect the lower semiconductor chip 210.

In some embodiments, an area of the upper surface of the lower semiconductor chip 210 may be smaller than an area of the upper surface of the upper semiconductor chip 220. In some embodiments, a sum of an area of the upper surface of the lower semiconductor chip 210 and an area of the upper surface of the chip molding layer 211 may be the same as an area of the upper semiconductor chip 220.

The lower molding layer ML1 may be located on the interposer 100 and on side surfaces of each of the plurality of lower stack structures 310 and side surfaces of the chip molding layer 211. The lower molding layer ML1 may surround side surfaces of each of the plurality of lower stack structures 310 and side surfaces of the chip molding layer 211. In some embodiments, a boundary surface 440 may be between the chip molding layer 211 and the lower molding layer ML1. For example, a curing time between the chip molding layer 211 and the lower molding layer ML1 may be different such that the boundary surface 440 may be between the chip molding layer 211 and the lower molding layer ML1. In another example, the chip molding layer 211 may be cured in advance of the lower molding layer ML1 such that the boundary surface 440 may be between the chip molding layer 211 and the lower molding layer ML1.

In some embodiments, the chip molding layer 211 may further include a mold through via 211_V. The mold through via 211_V may extend between the upper surface and the lower surface of the chip molding layer 211. For example, The redistribution layer RDL may be located on the lower molding layer ML1, the lower semiconductor chip 210, chip molding layer 211, mold through via 211_V, and the plurality of lower stack structures 310. The mold through via 211_V may be electrically connected to an upper pad 211_UP and a lower pad 211_DP of the chip molding layer 211. The lower pad 211_DP of the chip molding layer 211 may be electrically connected to the interposer 100 through the first connection terminal CT21. The upper pad 211_UP of the chip molding layer 211 may be electrically connected in direct contact with the redistribution layer RDL. For example, the mold through via 211_V may be electrically connected to the interposer 100 and the redistribution layer RDL.

In some embodiments, a width of the mold through via 211_V may be greater than a width of the chip through via 210_V. Power may be transmitted from the interposer 100 to the redistribution layer RDL through the mold through via 211_V. A signal may be transmitted from the interposer 100 to the redistribution layer RDL through the chip through via 210_V.

In some embodiments, a width of the upper pad 211_UP of the chip molding layer 211 and a width of the lower pad 211_DP of the chip molding layer 211 may be respectively greater than a width of the upper pad 210_UP of the lower semiconductor chip 210 and a width of the lower pad 210_DP of the lower semiconductor chip 210.

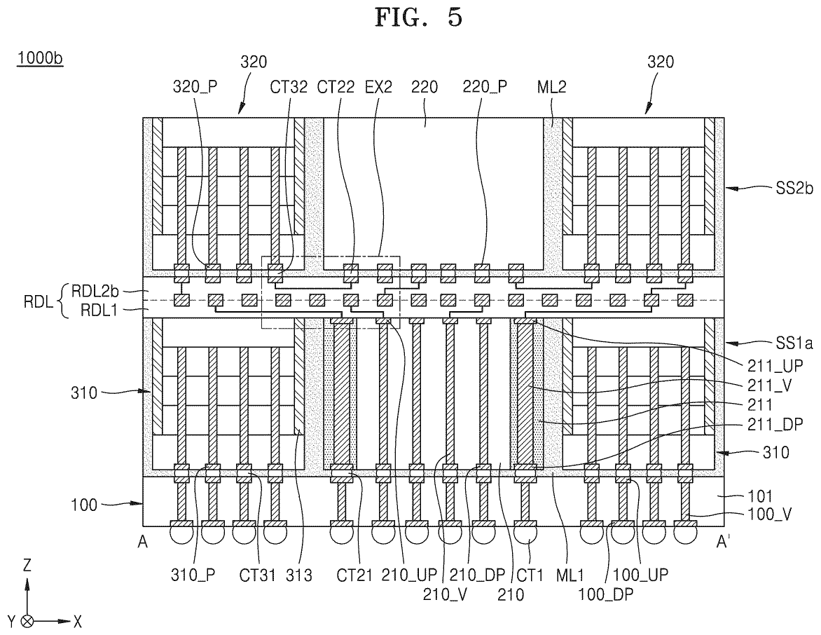

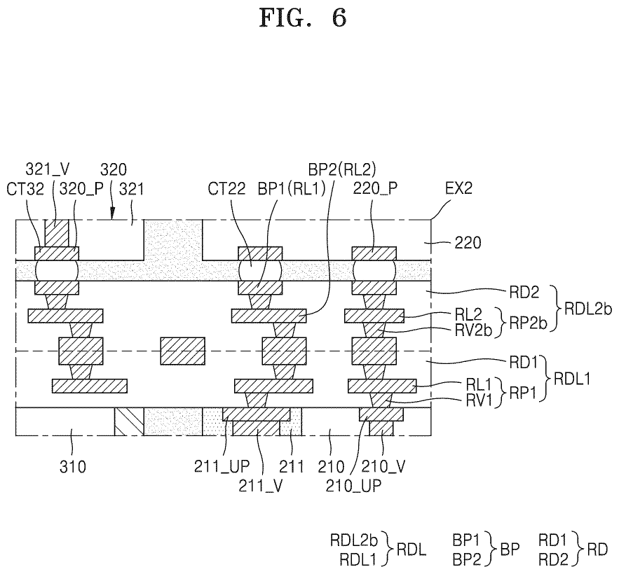

FIG. 5 is a cross-sectional view schematically showing a semiconductor package 1000b according to an embodiment. FIG. 6 is an enlarged view schematically showing a portion “EX2” of the semiconductor package 1000b of FIG. 5.

Referring to FIG. 5, the semiconductor package 1000b may include an interposer 100, the lower semiconductor chip 210, the chip molding layer 211, the plurality of lower stack structures 310, the lower molding layer ML1, the redistribution layer RDL, the upper semiconductor chip 220, the plurality of upper stack structures 320, and the upper molding layer ML2.

Certain components of the semiconductor package 1000b described below and materials of the components are substantially the same as or similar to those described above with reference to FIG. 4. Therefore, for convenience of explanation, repetitive descriptions thereof may be omitted or simplified.

An upper semiconductor device SS2b may include the upper redistribution layer RDL2b, the upper semiconductor chip 220, the plurality of upper stack structures 320, and the upper molding layer ML2.

The upper semiconductor chip 220 and the plurality of upper stack structures 320 may be mounted on the upper redistribution layer RDL2b. For example, a third connection terminal CT22 may be located between the upper semiconductor chip 220 and the upper redistribution layer RDL2b, and a fourth connection terminal CT32 may be located between each of the upper stack structures 320 and the upper redistribution layer RDL2b. The third connection terminal CT22 may electrically connect the lower pad 220_P of the upper semiconductor chip 220 to an upper redistribution pattern RP2b of the upper redistribution layer RDL2b. The fourth connection terminal CT32 may electrically connect a lower pad 320_P of the upper buffer chip 321 of each of the upper stack structures 320 to the upper redistribution pattern RP2b of the upper redistribution layer RDL2b. However, the upper semiconductor chip 220 and the plurality of upper stack structures 320 may be electrically connected to the upper redistribution layer RDL2b by an ACF, an NCF, direct bonding, or hybrid bonding. For example, the third connection terminal CT22 and the fourth connection terminal CT32 may be omitted.

In some embodiments, the upper redistribution pattern RP2b of the upper redistribution layer RDL2b may include the upper redistribution line RL2 and an upper redistribution via RV2b. A width of the upper redistribution via RV2b may decrease downward in a vertical direction. For example, the width of the upper redistribution via RV2b may be narrower toward the interposer 100.

In some embodiments, in a process of manufacturing the upper semiconductor device SS2b, the upper redistribution layer RDL2b may be manufactured on a carrier substrate, and the upper semiconductor chip 220 and the plurality of upper stack structures 320 may be mounted on the upper redistribution layer RDL2b. That is, the upper semiconductor device SS2b may be manufactured in a chip-last manner.

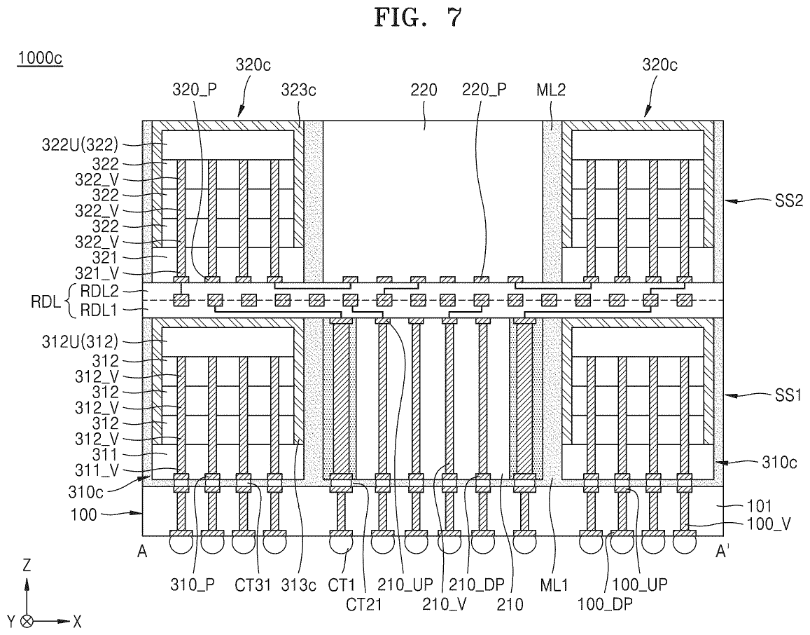

FIG. 7 is a cross-sectional view schematically showing a semiconductor package 1000c according to an embodiment.

Referring to FIG. 7, the semiconductor package 1000c may include an interposer 100, the lower semiconductor chip 210, a plurality of lower stack structures 310c, the lower molding layer ML1, the redistribution layer RDL, the upper semiconductor chip 220, a plurality of upper stack structures 320c, and the upper molding layer ML2.

Certain components of the semiconductor package 1000c described below and materials of the components are substantially the same as or similar to those described above with reference to FIG. 4. Therefore, for convenience of explanation, repetitive descriptions thereof may be omitted or simplified.

The plurality of lower stack structures 310c may be located on the interposer 100. Each of the plurality of lower stack structures 310c may include the lower buffer chip 311, the plurality of lower core chips 312, and the lower core molding layer 313c.

The lower core molding layer 313c may be located on the lower buffer chip 311 and may cover the plurality of lower core chips 312. For example, the lower core molding layer 313c may cover side surfaces of each of the plurality of lower core chips 312 and an upper surface of the uppermost lower core chip 312U. For example, the plurality of lower core chips 312 may be encapsulated by the lower core molding layer 313c. For example, the plurality of lower core chips 312 may be spaced apart from the lower molding layer ML1 with the lower core molding layer 313c disposed therebetween.

The plurality of upper stack structures 320c may be located on the redistribution layer RDL. Each of the plurality of upper stack structures 320c may include the upper buffer chip 321, the plurality of upper core chips 322, and an upper core molding layer 323c.

The upper core molding layer 323c may be located on the upper buffer chip 321 and may cover the plurality of upper core chips 322. For example, the upper core molding layer 323c may cover side surfaces of each of the plurality of upper core chips 322 and an upper surface of the uppermost upper core chip 322U. For example, the plurality of upper core chips 322 may be encapsulated by the upper core molding layer 323c. For example, the plurality of upper core chips 322 may be spaced apart from the upper molding layer ML2 with the upper core molding layer 323c disposed therebetween.

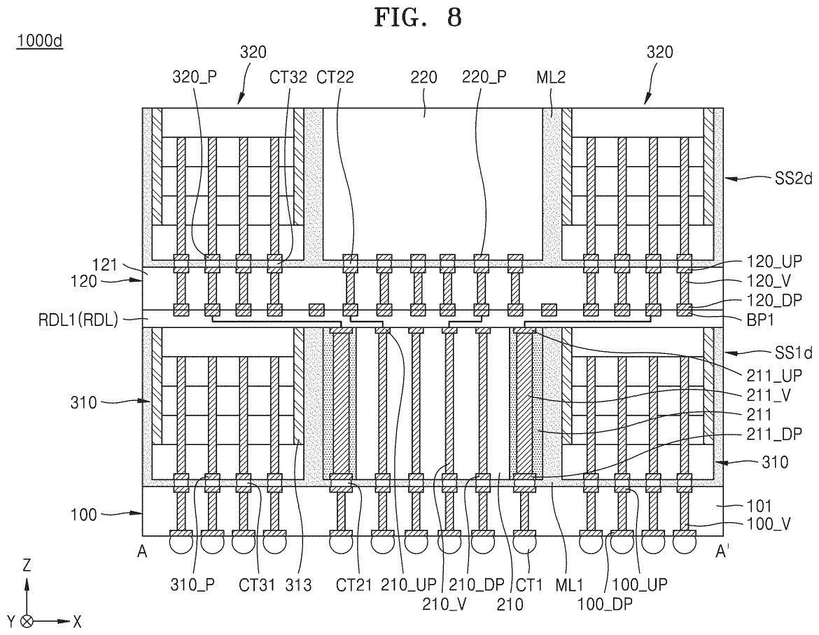

FIG. 8 is a cross-sectional view schematically showing a semiconductor package 1000d according to an embodiment.

Referring to FIG. 8, the semiconductor package 1000d may include the interposer 100, the lower semiconductor chip 210, the chip molding layer 211, the plurality of lower stack structures 310, the lower molding layer ML1, the redistribution layer RDL, an upper interposer 120, the upper semiconductor chip 220, the plurality of upper stack structures 320, and the upper molding layer ML2.

Certain components of the semiconductor package 1000d described below and materials of the components are substantially the same as or similar to those described above with reference to FIG. 4. Therefore, for convenience of explanation, repetitive descriptions thereof may be omitted or simplified.

An upper semiconductor device SS2d may include the upper interposer 120, the upper semiconductor chip 220, the plurality of upper stack structures 320, and the upper molding layer ML2. A lower semiconductor device SS1d may include the interposer 100, the lower semiconductor chip 210, the plurality of lower stack structures 310, the lower molding layer ML1, and the lower redistribution layer RDL1. The redistribution layer RDL of the semiconductor package 1000d may include the lower redistribution layer RDL1 and an upper redistribution layer may be omitted.

Hereinafter, the interposer 100 of the lower semiconductor device SS1d may be referred to as a lower interposer. For example, the semiconductor package 1000d may include a lower interposer and the upper interposer 120 overlapping in a vertical direction.

The upper interposer 120 may be located on the redistribution layer RDL. The upper semiconductor chip 220 and the plurality of upper stack structures 320 may be located on the upper interposer 120 and electrically connected to the upper interposer 120. The upper interposer 120 may transmit signals between the upper semiconductor chip 220 and the plurality of upper stack structures 320. The upper interposer 120 may transmit signals between the upper semiconductor chip 220 and the redistribution layer RDL. In some embodiments, in a plan view, an area of an upper surface of the upper interposer 120, an area of an upper surface of the redistribution layer RDL, and an area of an upper surface of the interposer 100 may be the same.

The upper interposer 120 may include a second substrate 121 and a second through via 120_V penetrating the second substrate 121. For example, the upper interposer 120 may be a glass interposer in which the second substrate 121 includes glass, and the second through via 120_V may be a TGV. However, the upper interposer 120 is not limited thereto, and may be a silicon interposer in which the second substrate 121 includes silicon and the second through via 120_V may be a TSV.

The upper interposer 120 may further include an upper pad 120_UP and a lower pad 120_DP. The upper pad 120_UP may be located on an upper surface of the second substrate 121 of the upper interposer 120, and the lower pad 120_DP may be located on a lower surface of the second substrate 121 of the upper interposer 120. Each of the upper pad 120_UP and the lower pad 120_DP may be electrically connected to a wiring region of the upper interposer 120. The upper pad 120_UP and the lower pad 120_DP may be electrically connected to each other by a second through via 120_V.

The third connection terminal CT22 may be located between the upper semiconductor chip 220 and the upper interposer 120, and the fourth connection terminal CT32 may be located between each of the plurality of upper stack structures 320 and the upper interposer 120. The third connection terminal CT22 may electrically connect the lower pad 220_P of the upper semiconductor chip 220 to the upper pad 120_UP of the upper interposer 120. The fourth connection terminal CT32 may electrically connect the lower pad 320_P of the upper buffer chip 321 of each of the plurality of upper stack structures 320 to the upper pad 120_UP of the upper interposer 120.

However, the upper semiconductor chip 220 and the plurality of upper stack structures 320 may be electrically connected to the upper interposer 120 by an ACF, an NCF, direct bonding, or hybrid bonding. For example, one or more of the third connection terminal CT22 or the fourth connection terminal CT32 may be omitted.

In a process of mounting the upper semiconductor device SS2d onto the lower semiconductor device SS1d, the upper interposer 120 of the upper semiconductor device SS2dmay be mounted on the lower redistribution layer RDL1 of the lower semiconductor device SS1d.

In some embodiments, the upper pad BP1 of the lower redistribution layer RDL1 and the lower pad 120_DP of the upper interposer 120 may be diffusion bonded by heat. For example, the lower redistribution layer RDL1 and the upper interposer 120 may be electrically and physically connected to each other. However, the upper interposer 120 and the lower redistribution layer RDL1 are not limited thereto, and may be electrically connected to each other by an ACF, an NCF, or a connection terminal.

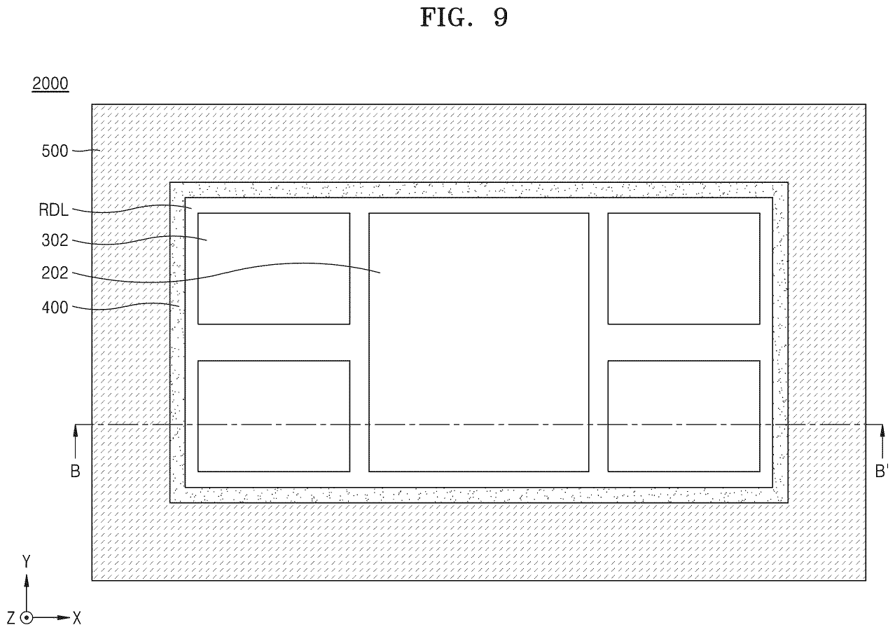

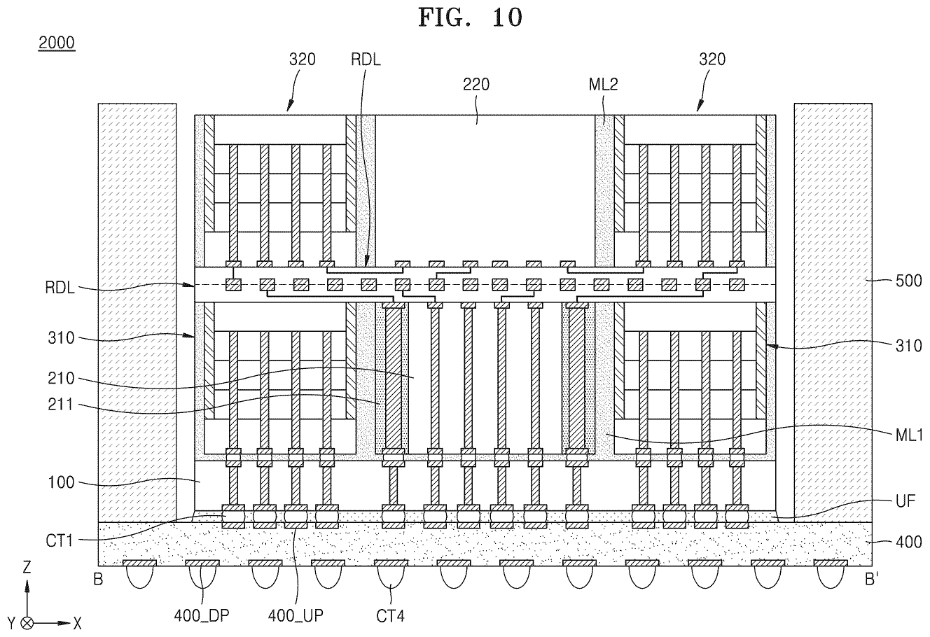

FIG. 9 is a plan view schematically showing a semiconductor package 2000 according to an embodiment. FIG. 10 is a cross-sectional view schematically showing the semiconductor package 2000 of FIG. 9 taken along line B-B′ of FIG. 9.

The semiconductor package 2000 of FIG. 10 may include a package substrate 400, the interposer 100, the lower semiconductor chip 210, the plurality of lower stack structures 310, the lower molding layer ML1, the redistribution layer RDL, the upper semiconductor chip 220, the plurality of upper stack structures 320, and the upper molding layer ML2.

In an embodiment, the semiconductor package 2000 of FIG. 10 may be a semiconductor package (such as, semiconductor package 1000 of FIG. 2, semiconductor package 1000a of FIG. 4, semiconductor package 1000b of FIG. 5, semiconductor package 1000c of FIG. 7, or semiconductor package 1000d of FIG. 8) mounted on the package substrate 400.

Certain components of the semiconductor package 200 described below and materials of the components are substantially the same as or similar to those described above with reference to FIG. 4. Therefore, for convenience of explanation, repetitive descriptions thereof may be omitted or simplified.

The package substrate 400 may be a printed circuit board (PCB) including a core insulating layer. The core insulating layer may have a flat plate shape or a panel shape. The core insulating layer may include an upper surface and a lower surface disposed opposite to the upper surface, and the upper surface and the lower surface of the core insulating layer may each be a flat surface. The core insulating layer may include at least one of phenol resin, epoxy resin, or polyimide.

For example, the core insulating layer may include at least one of a prepreg, polyimide, flame retardant 4 (FR-4), radioactive epoxy, polyphenylene ether, epoxy/polyphenylene oxide, bismaleimide triazine (BT), thermount, cyanate ester, or liquid crystal polymer.

The package substrate 400 may further include an upper pad 400_UP located on the upper surface of the core insulating layer and a lower pad 400_DP located on the lower surface of the core insulating layer. The upper pad 400_UP and the lower pad 400_DP may be electrically connected by a through via and/or an inner wiring. For example, each of the upper pad 400_UP and the lower pad 400_DP may include at least one of copper, nickel, stainless steel, or beryllium copper.

The interposer 100 may be located on the package substrate 400. In a plan view, an area of an upper surface of the package substrate 400 may be larger than an area of an upper surface of the interposer 100. The interposer 100 may be electrically connected to the upper pad 400_UP of the package substrate 400 through the external connection terminals CT1. In some embodiments, the package substrate 400 may further include an underfill layer UF. The underfill layer UF may be located between the interposer 100 and the package substrate 400 and may surround the external connection terminals CT1.

A plurality of external connection terminals CT4 may be attached to the lower pad 400_DP of the package substrate 400. The external connection terminals CT4 may be configured to electrically and physically connect the package substrate 400 and an external device on which the package substrate 400 is mounted. The external connection terminals CT4 may be formed from, for example, a solder ball or a solder bump.

The lower semiconductor chip 210, the plurality of lower stack structures 310, and the lower molding layer ML1 may be located on the interposer 100. The redistribution layer RDL may be located on the lower semiconductor chip 210 and the lower molding layer ML1. The upper semiconductor chip 220, the plurality of upper stack structures 320, and the upper molding layer ML2 may be located on the redistribution layer RDL.

In some embodiments, the redistribution layer RDL may be manufactured by combining a lower redistribution layer of the upper semiconductor device SS2 (refer to FIG. 2) and the upper redistribution layer of the lower semiconductor device SS1 (refer to FIG. 2). The upper semiconductor chip 220 and the lower semiconductor chip 210 may be substantially the same type of chip. For example, each of the upper semiconductor chip 220 and the lower semiconductor chip 210 may include an ASIC. The plurality of upper stack structures 320 and the plurality of lower stack structures 310 may be substantially the same type of stack structure. For example, each of the plurality of upper stack structures 320 and each of the plurality of lower stack structures 310 may be an HBM.

In some embodiments, the semiconductor package 2000 may further include a heat sink 500. The heat sink 500 may be located on the package substrate 400. For example, the heat sink 500 may be spaced apart from the interposer 100, the lower molding layer ML1, and the upper molding layer ML2 in a horizontal direction. However, the heat sink 500 is not limited thereto, and may contact side surfaces of each of the interposer 100, the lower molding layer ML1, and the upper molding layer ML2.

In some embodiments, the heat sink 500 may have a flat plate shape including a cavity extending from an upper surface to a lower surface, and the interposer 100, the lower semiconductor chip 210, the plurality of lower stack structures 310, the lower molding layer ML1, the redistribution layer RDL, the upper semiconductor chip 220, the plurality of upper stack structures 320, and the upper molding layer ML2 may be located in the cavity.

The heat sink 500 may be configured to dissipate heat generated by the semiconductor package 2000 to the outside of the semiconductor package 2000. The heat sink 500 may inhibit or prevent a shape of the package substrate 400 from being deformed by an external force.

The heat sink 500 may include a thermally conductive material having high thermal conductivity. For example, the heat sink 500 may include a metal such as copper (Cu) or aluminum (Al), or a carbon-containing material such as graphene, graphite, and/or a carbon nanotube. However, the material of the heat sink 500 is not limited to the above-described materials. In some embodiments, the heat sink 500 may include a single metal layer or a plurality of stacked metal layers.

In some embodiments, the heat sink 500 may be attached onto the package substrate 400 through a thermal interface material (TIM) layer. The TIM layer may include a thermally conductive and electrically insulating material. For example, the TIM layer may include a polymer including a metal powder such as silver or copper, thermal grease, white grease, or a combination thereof.

While the inventive concept has been particularly shown and described with reference to embodiments thereof, it will be understood that various changes in form and details may be made therein without departing from the spirit and scope of the following claims.

What is claimed is:

1. A semiconductor package comprising:
an interposer;
a lower semiconductor chip located on the interposer and comprising a chip through via;
a plurality of lower stack structures located on the interposer and spaced apart from the lower semiconductor chip in a horizontal direction;
a lower molding layer located on the interposer;
a redistribution layer located on the lower molding layer, the lower semiconductor chip, and the plurality of lower stack structures and electrically connected to the chip through via of the lower semiconductor chip;
an upper semiconductor chip located on the redistribution layer and electrically connected to the redistribution layer;
a plurality of upper stack structures spaced apart from the upper semiconductor chip in the horizontal direction, located on the redistribution layer, and electrically connected to the redistribution layer; and
an upper molding layer located on the redistribution layer and on side surfaces of the upper semiconductor chip and side surfaces of each of the plurality of upper stack structures.

2. The semiconductor package of claim 1, wherein
the redistribution layer includes a redistribution insulating layer and a plurality of bonding pads buried inside the redistribution insulating layer, and
vertical levels of the plurality of bonding pads inside the redistribution insulating layer are the same as each other.

3. The semiconductor package of claim 2, wherein
the redistribution layer includes a lower redistribution layer and an upper redistribution layer on the lower redistribution layer, and
each of the plurality of bonding pads of the redistribution layer included portions in the lower redistribution layer and the upper redistribution layer.

4. The semiconductor package of claim 3, wherein
the upper redistribution layer includes an upper redistribution line, an upper redistribution via extending in a vertical direction from the upper redistribution line, and an upper redistribution insulating layer surrounding the upper redistribution line and the upper redistribution via,
the lower redistribution layer includes a lower redistribution line, a lower redistribution via extending in a vertical direction from the lower redistribution line, and a lower redistribution insulating layer surrounding the lower redistribution line and the lower redistribution via,
a width of the upper redistribution via increases closer to the interposer, and
a width of the lower redistribution via decreases closer to the interposer.

5. The semiconductor package of claim 4, wherein the upper semiconductor chip and the plurality of upper stack structures are in contact with the upper redistribution via of the upper redistribution layer of the redistribution layer.

6. The semiconductor package of claim 3, wherein
the upper redistribution layer includes an upper redistribution line, an upper redistribution via extending in a vertical direction from the upper redistribution line, and an upper redistribution insulating layer surrounding the upper redistribution line and the upper redistribution via,
the lower redistribution layer includes a lower redistribution line, a lower redistribution via extending in the vertical direction from the lower redistribution line, and a lower redistribution insulating layer surrounding the lower redistribution line and the lower redistribution via, and
each of a thickness of the upper redistribution line and a thickness of the lower redistribution line is less than a thickness of each of the plurality of bonding pads.

7. The semiconductor package of claim 1, wherein an area of an upper surface of the interposer is same as an area of an upper surface of the redistribution layer.

8. The semiconductor package of claim 1, wherein
the lower molding layer is located on side surfaces of the lower semiconductor chip and side surfaces of each of the plurality of lower stack structures, and
an upper surface of the lower semiconductor chip, an upper surface of each of the plurality of lower stack structures, and an upper surface of the lower molding layer are coplanar.

9. The semiconductor package of claim 6, wherein
the lower semiconductor chip is in contact with one of the lower redistribution via and the lower redistribution line of the lower redistribution layer, and
the lower redistribution insulating layer of the lower redistribution layer covers an upper surface of each of the plurality of lower stack structures.

10. The semiconductor package of claim 1, wherein
the interposer is configured to transmit signals between the plurality of lower stack structures and the lower semiconductor chip and an exterior of the semiconductor package, and
the redistribution layer is configured to transmit signals between the plurality of upper stack structures and the upper semiconductor chip, and between the upper semiconductor chip and the lower semiconductor chip.

11. A semiconductor package comprising:
a lower interposer;
a lower semiconductor chip located on the lower interposer and comprising a chip through via;
a mold through via located on the lower interposer and electrically connected to the lower interposer, and spaced apart from the lower semiconductor chip in a horizontal direction;
a plurality of lower stack structures located on the lower interposer and spaced apart from the lower semiconductor chip in the horizontal direction;
a lower molding layer located on the lower interposer and on side surfaces of the lower semiconductor chip and side surfaces of each of the plurality of lower stack structures;
a redistribution layer located on the lower molding layer, the lower semiconductor chip, the mold through via, and the plurality of lower stack structures and configured to be electrically connected to the chip through via;
an upper semiconductor chip located on an upper portion of the redistribution layer and electrically connected to the redistribution layer;
a plurality of upper stack structures spaced apart from the upper semiconductor chip in the horizontal direction, located on an upper portion of the redistribution layer, and electrically connected to the redistribution layer; and
an upper molding layer located on an upper portion of the redistribution layer and on side surfaces of the upper semiconductor chip and side surfaces of each of the plurality of upper stack structures.

12. The semiconductor package of claim 11, wherein an area of an upper surface of the lower interposer is same as an area of an upper surface of the redistribution layer.

13. The semiconductor package of claim 11, wherein an area of an upper surface of the lower semiconductor chip is smaller than an area of an upper surface of the upper semiconductor chip.

14. The semiconductor package of claim 11, further comprising a chip molding layer located on the lower interposer and on the side surfaces of the lower semiconductor chip, wherein
the chip molding layer separates the side surfaces of the lower semiconductor chip from the lower molding layer,
the mold through via extends from an upper surface of the chip molding layer to a lower surface of the chip molding layer, and
the mold through via is electrically connected to the lower interposer and the redistribution layer.

15. The semiconductor package of claim 14, wherein a width of the mold through via is greater than a width of the chip through via.

16. The semiconductor package of claim 11, further comprising an upper interposer located on the redistribution layer,
wherein the upper semiconductor chip, the plurality of upper stack structures, and the upper molding layer are located on the upper interposer, and
the upper interposer electrically connects the upper semiconductor chip and the plurality of upper stack structures to the redistribution layer.

17. The semiconductor package of claim 11, wherein
the redistribution layer includes a redistribution insulating layer and a plurality of bonding pads buried inside the redistribution insulating layer, and
vertical levels of the plurality of bonding pads inside the redistribution insulating layer are the same as each other.

18. A semiconductor package comprising:
a package substrate;
an interposer located on the package substrate;
a lower semiconductor chip located on the interposer and comprising a chip through via;
a chip molding layer located on the interposer and on side surfaces of the lower semiconductor chip;
a plurality of lower stack structures located on the interposer and spaced apart from the lower semiconductor chip in a horizontal direction;
a lower molding layer located on the interposer and on side surfaces of the chip molding layer and side surfaces of each of the plurality of lower stack structures;
a redistribution layer located on the lower molding layer, the lower semiconductor chip, the chip molding layer, and the plurality of lower stack structures, configured to be electrically connected to the chip through via of the lower semiconductor chip, and comprising a redistribution insulating layer and a bonding pad located inside the redistribution insulating layer;
an upper semiconductor chip located on the redistribution layer and electrically connected to the redistribution layer;
an upper stack structure spaced apart from the upper semiconductor chip in a horizontal direction, located on the redistribution layer, and electrically connected to the redistribution layer; and
an upper molding layer located on the redistribution layer and on side surfaces of the upper semiconductor chip and side surfaces of the upper stack structure.

19. The semiconductor package of claim 18, wherein the redistribution layer includes a lower redistribution layer and an upper redistribution layer on the lower redistribution layer,
the upper redistribution layer includes an upper redistribution line, an upper redistribution via extending in a vertical direction from the upper redistribution line, and an upper redistribution insulating layer surrounding the upper redistribution line and the upper redistribution via,
the lower redistribution layer includes a lower redistribution line, a lower redistribution via extending in the vertical direction from the lower redistribution line, and a lower redistribution insulating layer surrounding the lower redistribution line and the lower redistribution via,
an upper portion of the bonding pad is disposed in the upper redistribution insulating layer, and a lower portion of the bonding pad is disposed in the lower redistribution insulating layer, and
a thickness of the bonding pad of the redistribution layer is greater than each of a thickness of the upper redistribution line of the upper redistribution layer and a thickness of the lower redistribution line of the lower redistribution layer.

20. The semiconductor package of claim 19, wherein
a width of the upper redistribution via increases closer to the interposer, and
a width of the lower redistribution via decreases closer to the interposer.
